(19) United States
(12) Patent Application Publication
(10) Pub. No.: US 2025/0321837 A1
(43) Pub. Date: Oct. 16, 2025

(54) SUB-BLOCK IN-FIELD READ OPERATION

(71) Applicant: MICRON TECHNOLOGY, INC., Boise, ID (US)

(72) Inventors: Yu-Chung Lien, San Jose, CA (US); Zhenming Zhou, San Jose, CA (US)

(21) Appl. No.: 19/081,087

(22) Filed: Mar. 17, 2025

Related U.S. Application Data
(60) Provisional application No. 63/634,638, filed on Apr. 16, 2024.

(51) Int. Cl. G06F 11/16; G06F 11/10; G06F 11/18

(52) U.S. Cl. CPC G06F 11/1612; G06F 11/1008; G06F 11/181

(57) ABSTRACT

A system includes a memory device and a processing device, operatively coupled with the memory device, to perform operations including performing a program operation to program data to a first block of a plurality of blocks of the memory device, wherein the program operation does not include a program verify phase; performing an in-field read operation to the first block, wherein the in-field read operation includes a voltage floating phase, and wherein a voltage supply to a wordline is withdrawn during the voltage floating phase; and responsive to detecting a read status failure as a result of performing the in-field read operation, marking and retiring the first block and performing the program operation to program the data to a second block of the plurality of blocks of the memory device.

### RELATED APPLICATIONS

This application claims the benefit of U.S. Provisional Patent Application No. 63/634,638 filed Apr. 16, 2024, entitled “SUB-BLOCK IN-FIELD READ OPERATION”, the contents of which are incorporated by reference in its entirety herein.

### TECHNICAL FIELD

Embodiments of the disclosure relate generally to memory sub-systems, and more specifically, relate to implementing an in-field read operation on one or more sub-blocks to detect defects in a memory device in a memory sub-system.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure.

FIG. 1A illustrates an example computing system that includes a memory sub-system, in accordance with one or more embodiments of the present disclosure.

FIG. 1B is a block diagram of memory device(s) in communication with a memory sub-system controller of a memory sub-system, in accordance with one or more embodiments of the present disclosure.

FIG. 2 is a schematic of portions of an array of memory cells used in a memory sub-system, in accordance with one or more embodiments of the present disclosure.

FIG. 3 is a flow diagram of an example method implementing an in-field read operation on one or more sub-blocks to detect defects in a memory device in a memory sub-system, in accordance with one or more embodiments of the present disclosure.

FIGS. 4A-4D illustrate example in-field read operations, in accordance with one or more embodiments of the present disclosure.

FIG. 5 is a flow diagram of another example method of implementing an in-field read operation on one or more sub-blocks to detect defects in a memory device in a memory sub-system, in accordance with one or more embodiments of the present disclosure.

FIG. 6 is a block diagram of an example computer system in which embodiments of the present disclosure may operate.

### DETAILED DESCRIPTION

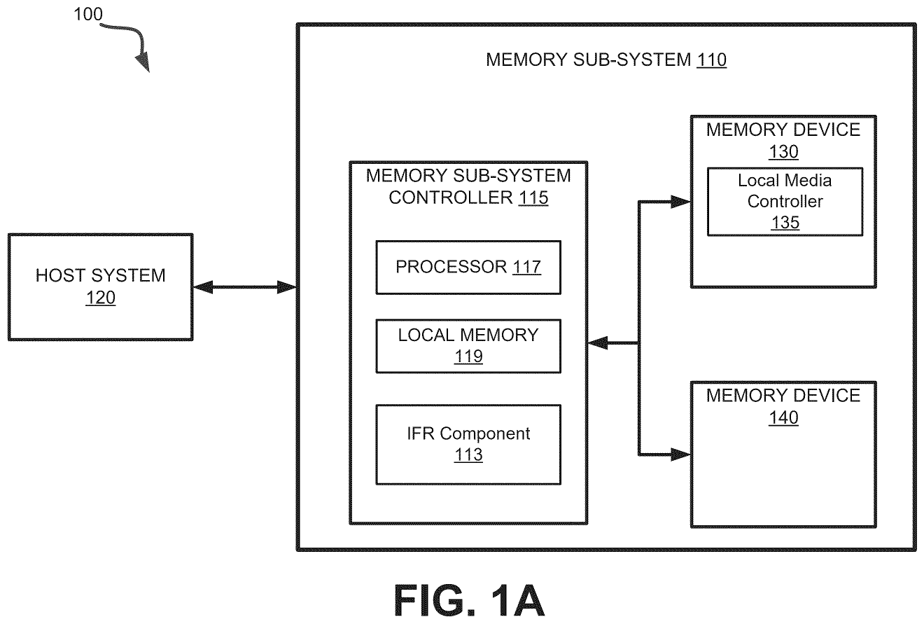

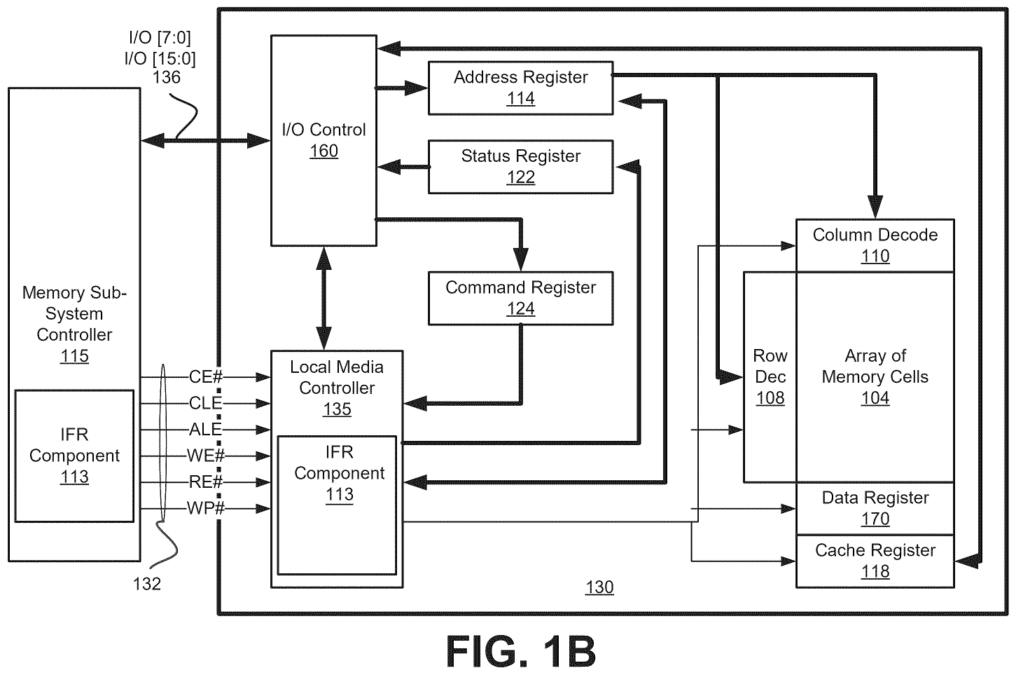

Aspects of the present disclosure are directed to implementing an in-field read operation on one or more sub-blocks to detect defects in a memory device in a memory sub-system. A memory sub-system can be a storage device, a memory module, or a hybrid of a storage device and memory module. Examples of storage devices and memory modules are described below in conjunction with FIG. 1A. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. For example, NAND memory, such as 3D flash NAND memory, offers storage in the form of compact, high density configurations. A non-volatile memory device is a package of one or more dice, each including one or more planes. For some types of non-volatile memory devices (e.g., NAND memory), each plane includes of a set of physical blocks. Each block includes of a set of pages. Each page includes of a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can be made up of bits arranged in a two-dimensional or a three-dimensional grid. Memory cells are formed onto a silicon wafer in an array of columns and rows. The memory cells are joined by wordlines, which are conducting lines electrically connected to the control gates of the memory cells, and bitlines, which are conducting lines electrically connected to the drain electrodes of the memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include a respective access line driver circuit and power circuit for each plane of the memory device to facilitate concurrent access of pages of two or more memory planes, including different page types.

One example of a memory sub-system is a solid-state drive (SSD) that includes one or more non-volatile memory devices and a memory sub-system controller to manage the non-volatile memory devices. A given segment of one of those memory devices (e.g., a block) can be characterized based on the programming state of the memory cells associated with wordlines contained within the segment. In some cases, during each program operation to a different wordline, a program pulse is generated to program the wordline followed by a separate program verify operation to verify the threshold voltages of the programmed cells of that wordline. The purpose of the program verify operation is to check whether the sub-block has been programmed to a particular threshold program verify voltage and determine whether the programming has completed. In some cases, the program verify operation is skipped such that a program pulse is applied with no subsequent verification during the program operation. A program operation without the program verify phase has demonstrated several advantages, such as reduced time of program operation, better sequential writing performance, and reduced energy consumption of program operation.

As described above, a non-volatile memory device can include a number of individual blocks, each having a set of one or more wordlines that are used to access the memory cells of the block. Over time, as memory access operations, including program operations, read operations, and erase operations, are repeatedly performed on the blocks of the memory device, certain defects can develop. Defects can occur in memory devices due to the manufacturing process and can occur during the operating life of the memory device. For example, an electrical short can develop between two adjacent wordlines. When a certain voltage, such as a program voltage, is applied to one of those wordlines, a current is developed, at least a portion of which can flow through the electrical short and onto the adjacent wordline. This portion of the current can be referred to as a “leakage current” or “wordline leakage”. Wordline leakage can impact the logical values programed to or read from the memory cells connected to the associated wordlines leading to errors on the memory device.

However, such defect cannot be detected when a program operation without the program verify phase is used. In some cases, the memory sub-system can employ an error detection/correction method (e.g., by using an error correction code (ECC)) capable of detecting the defect and correcting a certain number of errors, for example, at the time of the read operation. When the detection/correction method is not capable of correcting the errors within the data being read, an ECC failure can occur and can be referred to as an uncorrectable ECC error (UECC error). Certain physical defects, including a wordline to wordline short, are considered as UECC errors and, responsive to detecting such an error, the memory sub-system can retire the corresponding block such that it is not used to store data going forward. But retiring the corresponding block cannot recovery the data that has been already programmed. That is, the wordline leakage-related defects (e.g., current leakage from one wordline to another or to the substrate) still cause the faulty wordline to fail to program and corresponding data can be corrupted, resulting in data loss and a reduction in reliability.

Aspects of the present disclosure address the above and other issues by implementing an in-field read operation on one or more sub-blocks to detect defects in a memory device in a memory sub-system. The in-field read operation is a read operation, performed during the lifecycle of a memory device (“in-field”), to identify and retire defected memory block(s). The in-field read operation is specific to be used after a program operation without a program verify phase, and the purpose of the in-field read operation is not to retrieve (read) data, but to identify and retire defected memory block(s) (detect defects). The in-field read operation is more sensitive, compared to a normal read operation, in defect detection because the selected wordline in the in-field read operation is disconnected from the voltage supply and left floating for a time period (“voltage floating phase”), which can result in an amplified charge difference for detecting defects such as leakages. Also, because the outcome of the in-field read operation is defect detection, not data retrieving, the in-field read operation can be performed in parallel to multiple sub-blocks (“ganged”).

Specifically, a component of the memory sub-system or the memory device (e.g., in-field read (IFR) component) may determine that a program operation is performed to program data to a block of the memory device and that the program operation does not include a program verify phase. Because the program verify phase is to check whether a sub-block of the block has been programmed to a particular threshold program verify voltage and determine whether the programming has completed to check whether there is a program status failure, the data programed without a program verify phase will not check for the program status failure. In such cases, the IFR component may perform an in-field read operation to such sub-block.

In some implementations, to determine sub-blocks for performing the in-field read operation, the IFR component may identify (e.g., by selecting) one or more sub-blocks that tend to be subject to the defects. For example, the IFR component may determine whether a media healthy metric (e.g., a program erase cycle (PEC) count) associated with a sub-block satisfies a threshold criterion (e.g., a threshold value), and responsive to determining that the media healthy metric associated with the sub-block satisfies the threshold criterion (e.g., the PEC count exceeds the threshold value), select the sub-block to perform the in-field read operation. In some implementations, the IFR component may receive the media healthy metric information from other components of the memory sub-system or monitor the media healthy metric information itself. In some implementations, as described above, the IFR component may identify (e.g., by selecting) multiple sub-blocks such that the in-field read operation can be performed on these sub-blocks in parallel.

Performing the in-field read operation may involving applying voltages to wordlines such that a selected wordline (i.e., the target wordline for defect detection) is pre-charged during a charging time to a pass voltage level (Vpass) and then is biased to the read threshold voltage (Vwlrv), and then is disconnected from the voltage supply and left floating, while the unselected wordline (e.g., the adjacent wordlines of the target wordline) is set to a pass voltage level (Vpass). The result of the in-field read operation may involving measuring a current and comparing the current with reference values to determine whether the sub-blocks contains defects, and based on the determination, outputting a result indicating whether a read status failure of the block is detected or not.

In some implementations, responsive to detecting a read status failure as a result of performing the in-field read operation, the IFR component may mark the block and retire the block such that the block is no longer used by the memory sub-system. Because the data that is supposed to be programmed in the block may be affected by the defect detected in the block, the IFR component may retrieve the data, which may be still stored in a memory cache (e.g., hardware memory buffer), and switch to another block to program the data. Advantageously, the in-field read operation enables the re-programming of data after programming a block that becomes a hard failure, thereby avoiding data loss and reducing the corresponding reliability risk.

Advantages of the present disclosure include that the in-field read operation is executed during use of the blocks of the memory device, and enables a proactive recognition of memory defects, such that a read status failure is identified and the corresponding block is retired before data loss is incurred. The in-field read operation is used in the case that no program verify is performed during the program operation, and as such, the in-field read operation provides a mechanism to promote the data integrity while keeping the merits provided by program operation without program verify, such as reduced time of program operation, better sequential writing performance, and reduced energy consumption of program operation. Aspects of the present disclosure are configured to identify blocks that failed and re-program the data prior to data loss. In addition, typical systems employ program operation with program verify involving increased programming time, which has a negative impact on the overall performance of the memory sub-system.

FIG. 1A illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., one or more memory device(s) 130), or a combination of such.

A memory sub-system 110 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to different types of memory sub-system 110. FIG. 1A illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller, CXL controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a compute express link (CXL) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access the memory components (e.g., the one or more memory device(s) 130) when the memory sub-system 110 is coupled with the host system 120 by the physical host interface (e.g., PCIe or CXL bus). The physical host interface can provide an interface for passing control, address, data, and other signals between the memory sub-system 110 and the host system 120. FIG. 1A illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device(s) 130) include negative-and (NAND) type flash memory and write-in-place memory, such as three-dimensional cross-point (“3D cross-point”) memory. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory device(s) 130 can include one or more arrays of memory cells. One type of memory cell, for example, single level cells (SLC) can store one bit per cell. Other types of memory cells, such as multi-level cells (MLCs), triple level cells (TLCs), and quad-level cells (QLCs), can store multiple bits per cell. In some embodiments, each of the memory devices 130 can include one or more arrays of memory cells such as SLCs, MLCs, TLCs, QLCs, or any combination of such. In some embodiments, a particular memory device can include an SLC portion, and an MLC portion, a TLC portion, or a QLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, electrically erasable programmable read-only memory (EEPROM).

A memory sub-system controller 115 (or controller 115 for simplicity) can communicate with the memory device(s) 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processor 117 (e.g., a processing device) configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1A has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory device(s) 130. The memory sub-system controller 115 can be responsible for other operations such as wear leveling operations, garbage collection operations, error detection and error-correcting code (ECC) operations, encryption operations, caching operations, and address translations between a logical address (e.g., logical block address (LBA), namespace) and a physical address (e.g., physical block address) that are associated with the memory device(s) 130. The memory sub-system controller 115 can further include host interface circuitry to communicate with the host system 120 via the physical host interface. The host interface circuitry can convert the commands received from the host system into command instructions to access the memory device(s) 130 as well as convert responses associated with the memory device(s) 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory device(s) 130.

In some embodiments, the memory device(s) 130 include local media controllers 135 that operate in conjunction with memory sub-system controller 115 to execute operations on one or more memory cells of the memory device(s) 130. An external controller (e.g., memory sub-system controller 115) can externally manage the memory device 130 (e.g., perform media management operations on the memory device(s) 130). In some embodiments, a memory device 130 is a managed memory device, which is a raw memory device (e.g., memory array 104) having control logic (e.g., local controller 135) for media management within the same memory device package. An example of a managed memory device is a managed NAND (MNAND) device. Memory device(s) 130, for example, can each represent a single die having some control logic (e.g., local media controller 135) embodied thereon. In some embodiments, one or more components of memory sub-system 110 can be omitted.

In one embodiment, the memory sub-system 110 includes a IFR component 113 that can implement an in-field read operation on one or more sub-blocks in a segment (e.g., a memory block) of memory array 104 of memory device 130 to detect defects in the memory device. In an embodiment, one or more portions of the IFR component 113 of the memory sub-system controller 115 can be included in the local media controller 135. Further details with regards to the operations of IFR component 113 are described below.

FIG. 1B is a simplified block diagram of a first apparatus, in the form of a memory device 130, in communication with a second apparatus, in the form of a memory sub-system controller 115 of a memory sub-system (e.g., memory sub-system 110 of FIG. 1A), according to an embodiment. Some examples of electronic systems include personal computers, personal digital assistants (PDAs), digital cameras, digital media players, digital recorders, games, appliances, vehicles, wireless devices, mobile telephones and the like. The memory sub-system controller 115 (e.g., a controller external to the memory device 130), may be a memory controller or other external host device.

Memory device(s) 130 includes an array of memory cells 104 logically arranged in rows and columns. Memory cells of a logical row are connected to the same access line (e.g., a wordline) while memory cells of a logical column are selectively connected to the same data line (e.g., a bitline). A single access line may be associated with more than one logical row of memory cells and a single data line may be associated with more than one logical column. Memory cells of at least a portion of array of memory cells 104 are capable of being programmed to one of at least two target data states.

Row decode circuitry 108 and column decode circuitry 110 are provided to decode address signals. Address signals are received and decoded to access the array of memory cells 104. Memory device 130 also includes input/output (I/O) control circuitry 160 to manage input of commands, addresses and data to the memory device 130 as well as output of data and status information from the memory device(s) 130. An address register 114 is in communication with I/O control circuitry 160 and row decode circuitry 108 and column decode circuitry 110 to latch the address signals prior to decoding. A command register 124 is in communication with I/O control circuitry 160 and local media controller 135 to latch incoming commands.

A controller (e.g., the local media controller 135 internal to the memory device 130) controls access to the array of memory cells 104 in response to the commands and generates status information for the external memory sub-system controller 115, i.e., the local media controller 135 is configured to perform access operations (e.g., read operations, programming operations and/or erase operations) on the array of memory cells 104. The local media controller 135 is in communication with row decode circuitry 108 and column decode circuitry 110 to control the row decode circuitry 108 and column decode circuitry 110 in response to the addresses. In one embodiment, the memory sub-system controller 115 and the local media controller 135 include portions of the IFR component 113 which are configured to enable communication between the memory sub-system controller 115 and the local media controller 135 to perform the steps and operations associated with the management of the wordline leakage testing of one or more of memory device(s) 130, in accordance with embodiments of the present application.

The local media controller 135 is also in communication with a cache register 118. Cache register 118 latches data, either incoming or outgoing, as directed by the local media controller 135 to temporarily store data while the array of memory cells 104 is busy writing or reading, respectively, other data. During a program operation (e.g., write operation), data may be passed from the cache register 118 to the data register 170 for transfer to the array of memory cells 104; then new data may be latched in the cache register 118 from the I/O control circuitry 160. During a read operation, data may be passed from the cache register 118 to the I/O control circuitry 160 for output to the memory sub-system controller 115; then new data may be passed from the data register 170 to the cache register 118. The cache register 118 and/or the data register 170 may form (e.g., may form a portion of) a page buffer of the memory device 130. A page buffer may further include sensing devices (not shown in FIG. 1B) to sense a data state of a memory cell of the array of memory cells 204, e.g., by sensing a state of a data line connected to that memory cell. A status register 122 may be in communication with I/O control circuitry 160 and the local memory controller 135 to latch the status information for output to the memory sub-system controller 115.

Memory device(s) 130 receives control signals at the memory sub-system controller 115 from the local media controller 135 over a control link 132. For example, the control signals can include a chip enable signal CE #, a command latch enable signal CLE, an address latch enable signal ALE, a write enable signal WE #, a read enable signal RE #, and a write protect signal WP #. Additional or alternative control signals (not shown) may be further received over control link 132 depending upon the nature of the memory device 130. In one embodiment, memory device 130 receives command signals (which represent commands), address signals (which represent addresses), and data signals (which represent data) from the memory sub-system controller 115 over a multiplexed input/output (I/O) bus 136 and outputs data to the memory sub-system controller 115 over I/O bus 136.

For example, the commands may be received over input/output (I/O) pins [7:0] of I/O bus 136 at I/O control circuitry 160 and may then be written into command register 124. The addresses may be received over input/output (I/O) pins [7:0] of I/O bus 136 at I/O control circuitry 160 and may then be written into address register 114. The data may be received over input/output (I/O) pins [7:0] for an 8-bit device or input/output (I/O) pins [15:0] for a 16-bit device at I/O control circuitry 160 and then may be written into cache register 118. The data may be subsequently written into data register 170 for programming the array of memory cells 104.

In an embodiment, cache register 118 may be omitted, and the data may be written directly into data register 170. Data may also be output over input/output (I/O) pins [7:0] for an 8-bit device or input/output (I/O) pins [15:0] for a 16-bit device. Although reference may be made to I/O pins, they may include any conductive node providing for electrical connection to the memory device 130 by an external device (e.g., the memory sub-system controller 115), such as conductive pads or conductive bumps as are commonly used.

It will be appreciated by those skilled in the art that additional circuitry and signals can be provided, and that the memory device 130 of FIGS. 1A-1B has been simplified. It should be recognized that the functionality of the various block components described with reference to FIGS. 1A-1B may not necessarily be segregated to distinct components or component portions of an integrated circuit device. For example, a single component or component portion of an integrated circuit device could be adapted to perform the functionality of more than one block component of FIGS. 1A-1B. Alternatively, one or more components or component portions of an integrated circuit device could be combined to perform the functionality of a single block component of FIGS. 1A-1B. Additionally, while specific I/O pins are described in accordance with popular conventions for receipt and output of the various signals, it is noted that other combinations or numbers of I/O pins (or other I/O node structures) may be used in the various embodiments.

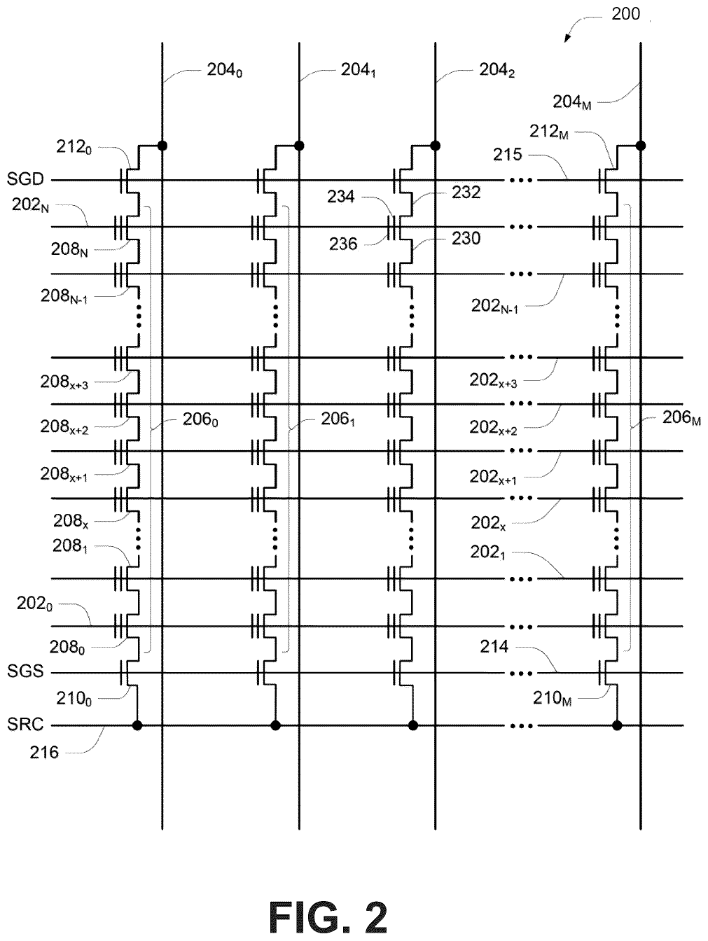

FIG. 2 is a schematic of portions of an array 200 of memory cells as could be used in a memory of the type described with reference to FIGS. 1A and 1B according to an embodiment. Memory array 200 includes access lines, such as wordlines 202₀ to 202_{N}, and data lines, such as bitlines 204₀ to 204_{M}. The wordlines 202 can be connected to global access lines (e.g., global word lines), not shown in FIG. 2, in a many-to-one relationship. For some embodiments, memory array 200 can be formed over a semiconductor that, for example, can be conductively doped to have a conductivity type, such as a p-type conductivity, e.g., to form a p-well, or an n-type conductivity, e.g., to form an n-well.

The memory array 200 can be arranged in rows (each corresponding to a wordline 202) and columns (each corresponding to a bitline 204). Each column can include a string of series-connected memory cells (e.g., non-volatile memory cells), such as one of NAND strings 206₀ to 206_{M}. Each NAND string 206 can be connected (e.g., selectively connected) to a common source (SRC) 216 and can include memory cells 208₀ to 208_{N}. The memory cells 208 can represent non-volatile memory cells for storage of data. The memory cells 208 of each NAND string 206 can be connected in series between a select gate 210 (e.g., a field-effect transistor), such as one of the select gates 210₀ to 210_{M} (e.g., that can be source select transistors, commonly referred to as select gate source), and a select gate 212 (e.g., a field-effect transistor), such as one of the select gates 212₀ to 212_{M} (e.g., that can be drain select transistors, commonly referred to as select gate drain). Select gates 210₀ to 210_{M} can be commonly connected to a select line 214, such as a source select line (SGS), and select gates 212₀ to 212_{M} can be commonly connected to a select line 215, such as a drain select line (SGD). Although depicted as traditional field-effect transistors, the select gates 210 and 212 can utilize a structure similar to (e.g., the same as) the memory cells 208. The select gates 210 and 212 can represent a number of select gates connected in series, with each select gate in series configured to receive a same or independent control signal.

A source of each select gate 210 can be connected to common source 216, or SRC. The drain of each select gate 210 can be connected to a memory cell 208₀ of the corresponding NAND string 206. For example, the drain of select gate 210₀ can be connected to memory cell 208₀ of the corresponding NAND string 206₀. Therefore, each select gate 210 can be configured to selectively connect a corresponding NAND string 206 to the common source 216. A control gate of each select gate 210 can be connected to the select line 214.

The drain of each select gate 212 can be connected to the bit line 204 for the corresponding NAND string 206. For example, the drain of select gate 212₀ can be connected to the bit line 204₀ for the corresponding NAND string 206₀. The source of each select gate 212 can be connected to a memory cell 208_{N} of the corresponding NAND string 206. For example, the source of select gate 212₀ can be connected to memory cell 208_{N} of the corresponding NAND string 206₀. Therefore, each select gate 212 can be configured to selectively connect a corresponding NAND string 206 to the corresponding bit line 204. A control gate of each select gate 212 can be connected to select line 215.

The memory array 200 in FIG. 2 can be a quasi-two-dimensional memory array and can have a generally planar structure, e.g., where the common source 216, NAND strings 206 and bit lines 204 extend in substantially parallel planes. Alternatively, the memory array 200 in FIG. 2 can be a three-dimensional memory array, e.g., where NAND strings 206 can extend substantially perpendicular to a plane containing the common source 216 and to a plane containing the bit lines 204 that can be substantially parallel to the plane containing the common source 216.

Typical construction of memory cells 208 includes a data-storage structure 234 (e.g., a floating gate, charge trap, or the like) that can determine a data state of the memory cell (e.g., through changes in threshold voltage), and a control gate 236, as shown in FIG. 2. The data-storage structure 234 can include both conductive and dielectric structures while the control gate 236 is generally formed of one or more conductive materials. In some cases, memory cells 208 can further have a defined source/drain (e.g., source) 230 and a defined source/drain (e.g., drain) 232. The memory cells 208 have their control gates 236 connected to (and in some cases form) a word line 202.

A column of the memory cells 208 can be a NAND string 206 or a number of NAND strings 206 selectively connected to a given bit line 204. A row of the memory cells 208 can be memory cells 208 commonly connected to a given wordline 202. A row of memory cells 208 can, but need not, include all the memory cells 208 commonly connected to a given wordline 202. Rows of the memory cells 208 can often be divided into one or more groups of physical pages of memory cells 208, and physical pages of the memory cells 208 often include every other memory cell 208 commonly connected to a given wordline 202. For example, the memory cells 208 commonly connected to wordline 202_{N} and selectively connected to even bit lines 204 (e.g., bitlines 204₀, 204₂, 204₄, etc.) can be one physical page of the memory cells 208 (e.g., even memory cells) while memory cells 208 commonly connected to word line 202_{N} and selectively connected to odd bit lines 204 (e.g., bitlines 204₁, 204₃, 204₅, etc.) can be another physical page of the memory cells 208 (e.g., odd memory cells).

Although bitlines 204₃-204₅ are not explicitly depicted in FIG. 2, it is apparent from the figure that the bitlines 204 of the array of memory cells 200 can be numbered consecutively from bitline 204₀ to bitline 204_{M}. Other groupings of the memory cells 208 commonly connected to a given wordline 202 can also define a physical page of memory cells 208. For certain memory devices, all memory cells commonly connected to a given word line can be deemed a physical page of memory cells. The portion of a physical page of memory cells (which, in some embodiments, could still be the entire row) that is read during a single read operation or programmed during a single program operation (e.g., an upper or lower page of memory cells) can be deemed a logical page of memory cells. A block of memory cells can include those memory cells that are configured to be erased together, such as all memory cells connected to wordlines 202₀-202_{N} (e.g., all NAND strings 206 sharing common wordlines 202). Unless expressly distinguished, a reference to a page of memory cells herein refers to the memory cells of a logical page of memory cells. Although the example of FIG. 2 is discussed in conjunction with NAND flash, the embodiments and concepts described herein are not limited to a particular array architecture or structure, and can include other structures (e.g., SONOS, phase change, ferroelectric, etc.) and other architectures (e.g., AND arrays, NOR arrays, etc.).

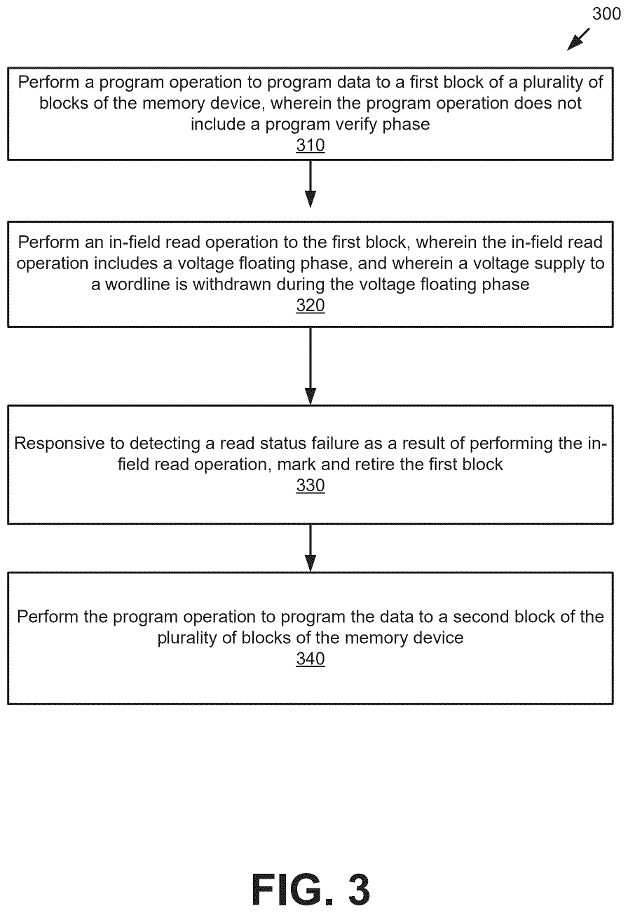

FIG. 3 is a flow diagram of an example method of implementing an in-field read operation on one or more sub-blocks to detect defects in a memory device in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by IFR component 113 of FIGS. 1A and 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 310, the processing device may perform a program operation to program data on a set of memory cells in a block of the blocks of the memory device, where the program operation does not include a program verify phase. In some implementations, the program operation may be in a one-pulse, zero-verify (1P0V) (i.e., a single programming pulse with no subsequent verification) program voltage pattern. The 1P0V program voltage pattern may include one program pulse associated with a program voltage applied to a selected wordline during one time period that corresponds to the program pulse phase, and no program verify phase exists. In some implementations, the program operation may be in a multiple-pulse, zero-verify (nP0V) (i.e., multiple programming pulses with no subsequent verification) program voltage pattern. The nP0V program voltage pattern may include multiple program pulses each associated with a program voltage applied to a selected wordline during a respective time period, together that corresponds to the program pulse phase, and no program verify phase exists. Because there is no program verify during the program operation, no program status failure will be detected.

In some implementations, the processing device may determine whether the program operation performed does not include a program verify phase, and responsive to determining that the program operation performed does not include a program verify phase, perform the in-field read operation. For example, the processing device may perform such determination by checking a configuration register that stores the information regarding the program voltage pattern to determine whether the program voltage pattern does not include a program verify phase.

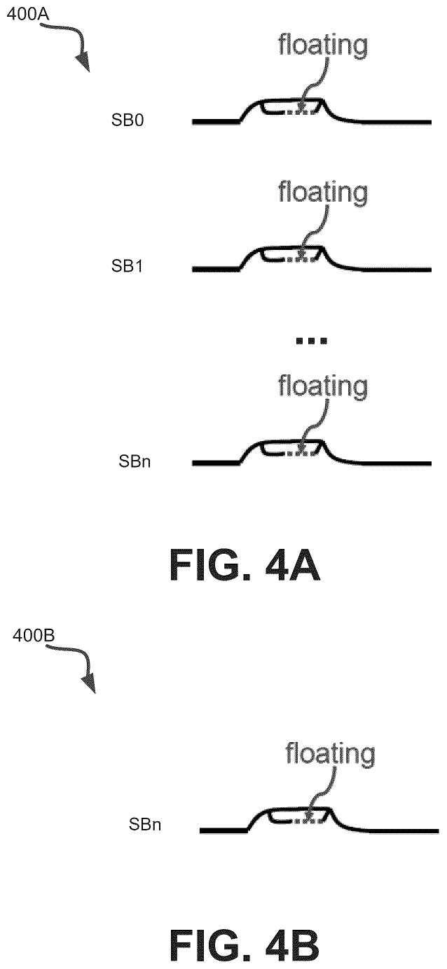

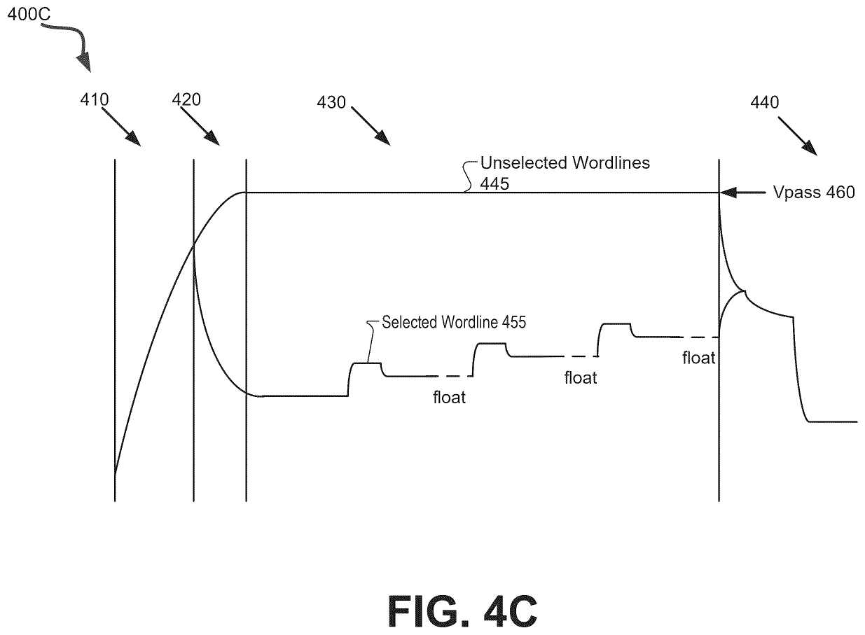

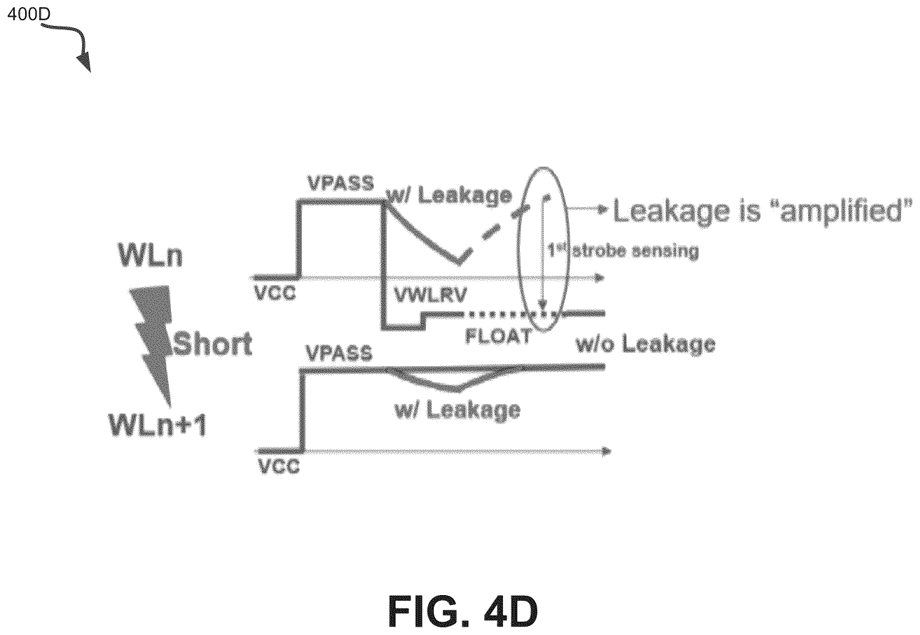

At operation 320, the processing device may perform an in-field read operation to the block, where the in-field read operation includes a voltage floating phase, and a voltage supply to a wordline is withdrawn during the voltage floating phase. The in-field read operation is similar to a read operation except that the in-field read operation includes a phase floating the voltage. The details of the in-field read operation will be described with respect to FIGS. 4A-4D. FIGS. 4A-4D illustrate examples of in-field read operations. In some implementations, the processing device may perform an in-field read operation in a “gang” or “group” mode as described with respect to FIG. 4A or in a “single” mode as described with respect to FIG. 4B. FIG. 4C illustrates a voltage applied to the selected wordlines and a voltage applied to the unselected wordlines during the in-field read operation. FIG. 4D illustrates example waveforms for detecting read status failure when execution of an in-field read operation on a block.

In some implementations, to determine sub-blocks for performing the in-field read operation, the processing device may identify (e.g., by selecting) one or more sub-blocks that tend to be subject to the defects. For example, the processing device may select sub-blocks that are operating beyond defined specifications of the memory device (e.g., which might dictate a certain time period and/or a temperature range for which the data is still recoverable) and might experience a higher quantity of read failures. An example of selecting the sub-blocks is described with respect to FIG. 4A.

Referring to FIG. 4A, in the “gang” or “group” mode, the IFR operation is executed with respect to a group of the sub-blocks of the block. In an embodiment, the IFR operation is executed in a “gang” or “group” mode in which the IFR operation is executed on a group of sub-blocks of the block in parallel. The IFR operation is executed in parallel on each of the group of sub-blocks of the block. As shown in FIG. 4A, the processing device may perform an IFR operation to each of a group of sub-blocks (e.g., SB0, SB1, . . . . SBn) in parallel. In some implementations, the block is partitioned into multiple sub-blocks, and the processing device may identify the sub-blocks by determining whether a media healthy metric associated with a specific sub-block satisfies a threshold criterion, and responsive to determining that the media healthy metric associated with the sub-block satisfies the threshold criterion, selecting the specific sub-block to be included in the group of the sub-blocks. The threshold criterion may be pre-defined. The media healthy metric refers to a quantity that is measured or inferred from the state of data stored on the memory device. The media healthy metric may indicate whether the cell can reliably store charges due to intrinsic cell degradation resulting from repeated stresses (e.g., repeated memory access operations). The media healthy metric may be used to characterize voltage distributions, and reflect (i.e., is equal to or derived by a known transformation from) the state of slow charge loss, the degree of latent read disturb, the temporal voltage shift, and/or other measurable functions of the data state.

In one example, the media healthy metric may be represented by a program erase cycle (PEC) count and/or a temperature measurement. In some implementations, the processing device may compare the PEC count associated with a specific sub-block to a threshold PEC count value and determine that the media healthy metric satisfies the threshold criterion when the PEC count exceeds or reaches the threshold PEC count value. In some implementations, the processing device may compare a temperature of the specific sub-block to a threshold temperature range (e.g., including a minimum temperature level (e.g., 40° C.) and a maximum temperature level (e.g., 60° C.)) and determine that the media healthy metric satisfies the threshold criterion when the temperature exceeds the threshold temperature range.

In another example, the media healthy metric may be represented by the raw bit error rate (RBER), which is the number of bit error experienced by a given data block per unit of time. The media healthy metric may reflect the failed byte count (CFByte) and/or the failed bit count (CFBit) for a given set of memory cells. CFByte reflects the number of bytes in the sensed data that have at least one non-conducting bitline. In some embodiments, CFByte can reflect the number of bytes in the sensed data where the last bitline of the byte is a non-conducting bitline. CFBit reflects the number of non-conducting bitlines in the sensed data. In some implementations, the processing device may determine that the media healthy metric associated with a specific sub-block satisfies a threshold criterion when CFByte, or CFBit is more than or equal to a threshold value.

Referring to FIG. 4B, in a “single” mode, the IFR operation is executed with respect to one sub-block of the block. As shown in FIG. 4B, the processing device may perform an in-field read operation to one sub-block (e.g., SBn).

FIG. 4C is a timing diagram 400C for an IFR operation, in accordance with some embodiments of the present disclosure. In at least one embodiment, the operations of timing diagram 400C can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the operations of timing diagram 400C are performed by memory sub-system controller 115 or IFR component 113 of FIG. 1A and FIG. 1B. During a read operation performed on a non-volatile memory device, such as memory device 130, certain voltages can be applied to wordlines. FIG. 4C illustrates a voltage across the unselected wordlines 445 and a voltage across the selected wordlines 455 during the read operation. In at least one embodiment, unselected wordlines 445 can be coupled with memory cells not selected for the read operation. In at least one embodiment, unselected wordlines 445 can refer to the remaining wordlines. In this embodiment, the read operation includes four (4) time intervals (e.g., time interval 410, time interval 420, time interval 430, and time interval 440). It should be noted, each time interval is an example and is not limiting on the claims. That is, each time interval can be longer or shorter than illustrated in FIG. 4C in some embodiments. Other time intervals are possible.

During time interval 410, IFR component 113 can cause a bias to be applied to the unselected wordlines 445 and selected wordlines 455. In at least one embodiment, the IFR component 113 is configured to cause a first voltage to be applied to unselected wordlines 445. In one example, the first voltage is pass through voltage (VPass) 460. In at least one embodiment, the IFR component 113 is configured to cause the first voltage to be applied to the unselected wordlines 445 via a first voltage source. In a least one embodiment, the IFR component 113 is also configured to bias the select gate drain (SGD) 212 and select gate source (SGS) 210 to activate the SGD 212 and SGS 210, respectively.

During time interval 420, the voltage application component can continue causing the first voltage to be applied to the unselected wordlines, e.g., continue causing the first voltage to be applied to the unselected wordlines since they are not biased to the first voltage, e.g., not biased to Vpass 460. In at least one embodiment, the IFR component 113 can initiate the read operation when the selected wordlines 455 are biased to the second voltage, which can still exceed all threshold voltages of memory cells coupled with the selected wordline 455. In at least one embodiment, the IFR component 113 can selectively discharge the selected wordline 455 during the time interval 420. In at least one embodiment, the IFR component 113 can discharge the selected wordlines 455 to a first read voltage (e.g., a first read threshold voltage).

During time interval 430, the IFR component 113 can determine the unselected wordlines 445 are biased to the first voltage, e.g., biased to Vpass 460. In at least one embodiment, the IFR component 113 can refrain from applying or discharge a voltage at the unselected SGS 210 and SGD 212, e.g., the IFR component 113 can turn off the unselected SGS 210 and SGD 212 to maintain the unselected wordlines 445 at the first voltage. In at least one embodiment, the IFR component 113 can perform the read operation during the time interval 430. For example, the IFR component 113 can cause the selected wordlines 455 to be biased to the first read threshold voltage and perform a first read with floating (e.g., the “float” state as denoted by the dashed line in FIG. 4C) at the end of the first read. The IFR component 113 can then cause the selected wordlines 455 to be biased to a second read threshold voltage and perform a second read with floating (e.g., the “float” state as denoted by the dashed line in FIG. 4C) at the end of the second read, and so on until all read threshold voltages are applied to the selected wordlines 455, e.g., all possible read threshold of a memory cell are applied to the selected wordlines. In at least one embodiment, a number of read threshold voltages applied to the selected wordline 455 can depend on a number of bits stored by a memory cell. In one example, four (4) read thresholds can be applied to a multi-bit cell and eight (8) read threshold voltages can be applied for a triple level cell (TLC), and so forth. In one embodiment, a read threshold voltage during a page read can depend on a page type. For example, for a multi-level cell (MLC) a lower page read can use one read threshold voltage and an upper page read can use two read threshold voltages. In one embodiment, for TLC memory, the read threshold voltage can be dependent on a gray code of the system—e.g., a lower page can use two (2) read threshold voltages, an upper page read can use three (3) read threshold voltages, and an extra page can use two (2) read threshold voltages.

During time interval 440, the IFR component 113 can discharge the unselected wordlines 445. In at least one embodiment, the IFR component 113 can also discharge the selected wordline 455 and turn off the selected SGS 210 and SGD 212. In some embodiments, the memory device can determine a state or logic state of a memory cell after the time interval 440.

Performing an in-field read operation on one or more sub-blocks can result in a detection of a read status failure or no detection of read status failure of the block. FIG. 4D illustrates example waveforms for detecting read status failure when execution of a IFR operation on a block. In an embodiment, the IFR operation is executed to detect a read status failure by identifying leakage from a high voltage level to a low voltage level. Specifically, a selected wordline WLn for detection is pre-charged during a charging time to a pass voltage level (Vpass) and then is biased to the first read threshold voltage (Vwlrv), and then is disconnected from the voltage supply and left floating (e.g., the “float” state as denoted by the dashed line in FIG. 4D). The unselected wordline WLn+1 (e.g., the wordlines that are not being tested) is set to a pass voltage level (Vpass). In an embodiment, the internal current source (ICS) of the selected wordline WLn starts to decrease before the start of floating and then ramps up to a high level because of floating, which results in an amplified difference of the current compared with the case without floating. The amplified difference may be interpreted into the failed byte count (CFByte) and/or the failed bit count (CFBit), and according to the failed byte count (CFByte) and/or the failed bit count (CFBit), the proceeding device can set a read status failure or not. For example, if the selected wordline has any leakage to the adjacent unselected wordlines, the amplified difference may be greater than or equal to the reference value, and the proceeding device can determine that a wordline leakage occurs. Responsive to determining that a wordline leakage occurs in one wordline, the proceeding device can determine that a read status failure occurs in the block. In an embodiment, after determining whether a wordline leakage of the selected wordline occurs, the proceeding device continues to detect if all of the wordlines of the block have wordline leakage, and if any wordline of the block is detected to have the wordline leakage, the proceeding device can determine that a read status failure occurs in the block.

Referring back to FIG. 3, at operation 330, responsive to detecting a read status failure as a result of performing the in-field read operation, the processing device may mark the block and retire the block, and at operation 340, perform the program operation to program the data to another block. In some implementations, marking the block may represent that the block is a grown bad block (GBB). A GBB is a “bad block” that have experienced intrinsic cell degradation, and a bad block do not reliably store data due to a physical defect, such as blocks with intrinsic NAND defects and blocks with intrinsic cell degradation.

In an embodiment, to mark the block, a status register bit (e.g., SR [0]) can be set to a first value (e.g., “0”) if no read status failure is detected or a second value (e.g., “1”) if a read status failure is detected. In an embodiment, the processing device may perform the program operation to program the data to another block similar to the operation 310. The processing device may continue the process of operations 310 and 320 until no read status failure as a result of performing the in-field read operation, which means the program operation is successfully performed to a block that has passed a defect check. In some implementations, the data that to be programed is stored in a memory cache such as hardware memory buffer, and after the program operation is successfully performed to program the data, the data stored on the memory cache may be erased such that the memory cache is released for other use.

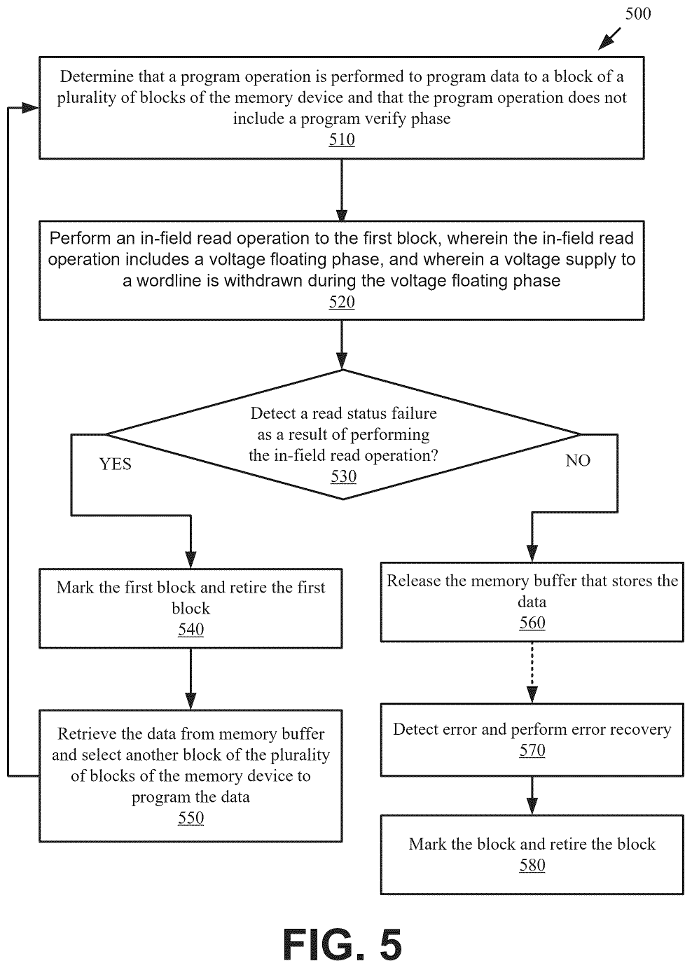

FIG. 5 is a flow diagram of an example method of managing wordline leakage testing of a memory block of a memory device in a memory sub-system, in accordance with one or more embodiments of the present disclosure. The method 500 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 500 is performed by IFR component 113 of FIGS. 1A and 1B. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At operation 510, the processing logic (e.g., IFR component 113) determines that a program operation is performed to program data to a block of a plurality of blocks of the memory device and that the program operation does not include a program verify phase. For example, the processing logic may receive an indication regarding a performance of program operation and check a configuration register that stores the information regarding the program voltage pattern to determine whether the program operation performed does not include a program verify phase. In another example, the processing logic may itself perform the program operation and thus can determine whether the program operation does not include a program verify phase. The program operation involved in the operation 510 may be same as or similar to that described in the operation 310.

At operation 520, responsive to determining that a program operation is performed to program data to a block of a plurality of blocks of the memory device and that the program operation does not include a program verify phase, the processing device may perform an in-field read operation to the wordline in the block, where the in-field read operation includes a voltage floating phase, and a voltage supply to the wordline is withdrawn during the voltage floating phase. The operation 520 may be same as or similar to the operation 320.

At operation 530, the processing device may determine whether a read status failure is detected as a result of performing the in-field read operation. The in-field read operation involved in the operation 530 may be same as or similar to that described in the operation 320 and the examples described in FIGS. 4A-4D.

Responsive to determining that a read status failure is detected as a result of performing the in-field read operation, at operation 540, the processing device may mark the block failure and retire the block, which may be same as or similar to the operation 340, and at operation 550, the processing device may retrieve the data from memory buffer and select another block of the plurality of blocks of the memory device to program the data, which may be same as or similar to the operation 350. After the operation 550, the processing device may process iteratively back to operation 510 until there is no read status failure is detected as a result of performing the in-field read operation at operation 530.

Responsive to determining that no read status failure is detected as a result of performing the in-field read operation, at operation 560, the processing device may release the memory buffer that stores the data, which indicates that the data has been successfully programmed to the block.

In some implementations, the processing device may perform a regular read operation (not in-field read operation) on the block of the memory device, and for example, at operation 570, the processing device may detect error(s) (e.g., UECC error) and perform error recovery operation (e.g., a redundant array of independent NAND (RAIN) operation), and at operation 580, the processing device may mark the block and retire the block, similarly as described above in operation 330. The RAIN operation may successfully recover data from memory cells in some instances when a read error handling operation fails. The RAIN operation can use the recovery metadata to reconstruct or recalculate the data in the event of a failure of the memory cells storing the data. The recovery metadata may be block-level striped, and include redundancy data (e.g., duplicate data, parity data), error detection data (e.g., error detection codes, checksums, cyclic redundancy check (CRC)), error correction data (e.g., error correcting code (ECC), forward error correction (FEC), erasure code), other data, or a combination thereof.

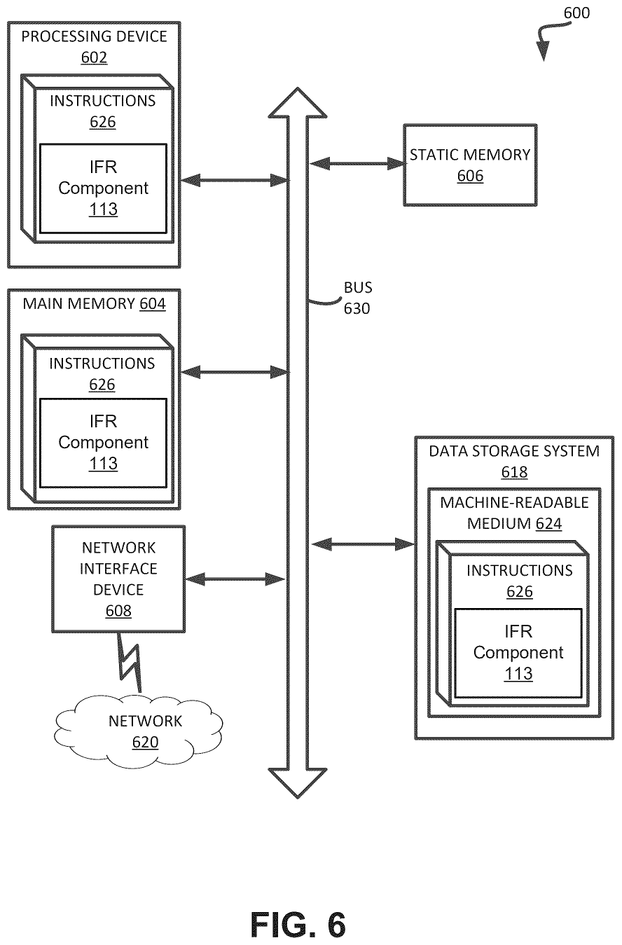

FIG. 6 illustrates an example machine of a computer system 600 within which a set of instructions, for causing the machine to perform any one or more of the methodologies discussed herein, can be executed. In some embodiments, the computer system 600 can correspond to a host system (e.g., the host system 120 of FIG. 1A) that includes, is coupled to, or utilizes a memory sub-system (e.g., the memory sub-system 110 of FIGS. 1A and 1B) or can be used to perform the operations of a controller (e.g., to execute an operating system to perform operations corresponding to the IFR component 113 of FIGS. 1A and 1B). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 600 includes a processing device 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a data storage system 618, which communicate with each other via a bus 630.

Processing device 602 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 602 can also be one or more special-purpose processing devices such as an application specific integrated circuit (ASIC), a field programmable gate array (FPGA), a digital signal processor (DSP), network processor, or the like. The processing device 602 is configured to execute instructions 626 for performing the operations and steps discussed herein. The computer system 600 can further include a network interface device 608 to communicate over the network 620.

The data storage system 618 can include a machine-readable storage medium 624 (also known as a computer-readable medium) on which is stored one or more sets of instructions 626 or software embodying any one or more of the methodologies or functions described herein. The instructions 626 can also reside, completely or at least partially, within the main memory 604 and/or within the processing device 602 during execution thereof by the computer system 600, the main memory 604 and the processing device 602 also constituting machine-readable storage media. The machine-readable storage medium 624, data storage system 618, and/or main memory 604 can correspond to the memory sub-system 110 of FIGS. 1A and 1B.

In one embodiment, the instructions 626 include instructions to implement functionality corresponding to the IFR component 113 of FIGS. 1A and 1B). While the machine-readable storage medium 624 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled with the memory device, to perform operations comprising:
performing a program operation to program data to a first block of a plurality of blocks of the memory device, wherein the program operation does not include a program verify phase;
performing an in-field read operation to the first block, wherein the in-field read operation includes a voltage floating phase, and wherein a voltage supply to a wordline is withdrawn during the voltage floating phase; and
responsive to detecting a read status failure as a result of performing the in-field read operation, marking and retiring the first block and performing the program operation to program the data to a second block of the plurality of blocks of the memory device.

2. The system of claim 1, wherein performing the programming operation to program the data to the second block comprises:
retrieving the data from a memory buffer; and
programming the data to the second block.

3. The system of claim 1, the operations further comprise:
responsive to detecting no read status failure as the result of performing the in-field read operation, releasing the data from a memory buffer, wherein releasing the data indicates that the data is successfully programmed to the first block.

4. The system of claim 3, the operations further comprise:
receiving a read command associated with the first block;
detecting an uncorrected error correction code (UECC) error in the first block;
performing an error recovery operation on the first block; and
marking and retiring the first block.

5. The system of claim 1, wherein performing the in-field read operation to the first block further comprises:
selecting a set of sub-blocks of the first block; and
performing the in-field read operation on each sub-block of the set of sub-blocks in parallel.

6. The system of claim 5, wherein selecting the set of sub-blocks of the first block further comprises:
determining whether a media healthy metric associated with a sub-block of a plurality of sub-blocks of the first block satisfies a threshold criterion; and
responsive to determining that the media healthy metric associated with the sub-block satisfies the threshold criterion, selecting the sub-block.

7. The system of claim 1, wherein performing the in-field read operation to the first block further comprises:
determining a sub-block of the first block; and
performing the in-field read operation to the sub-block of the first block.

8. The system of claim 1, wherein the in-field read operation comprises applying to the wordline a pass voltage followed by a bias voltage, wherein the floating voltage phase occurs during applying the bias voltage.

9. The system of claim 1, wherein the first block comprises memory cells configured as at least one of: single level cell (SLC) memory, multi-level cell (MLC) memory, triple level cell (TLC) memory, or quad-level cell (QLC) memory.

10. A method comprising:
performing, by a processing device, a program operation to program data to a first block of a plurality of blocks of the memory device, wherein the program operation does not include a program verify phase;
performing an in-field read operation to the first block, wherein the in-field read operation includes a voltage floating phase, and wherein a voltage supply to a wordline is withdrawn during the voltage floating phase; and
responsive to detecting a read status failure as a result of performing the in-field read operation, marking and retiring the first block and performing the program operation to program the data to a second block of the plurality of blocks of the memory device.

11. The method of claim 10, wherein performing the programming operation to program the data to the second block comprises:
retrieving the data from a memory buffer; and
programming the data to the second block.

12. The method of claim 10, further comprising:
responsive to detecting no read status failure as the result of performing the in-field read operation, releasing the data from a memory buffer, wherein releasing the data indicates that the data is successfully programmed to the first block.

13. The method of claim 12, further comprising:
receiving a read command associated with the first block;
detecting an uncorrected error correction code (UECC) error in the first block;
performing an error recovery operation on the first block; and
marking and retiring the first block.

14. The method of claim 10, wherein performing the in-field read operation to the first block further comprises:
selecting a set of sub-blocks of the first block; and
performing the in-field read operation on each sub-block of the set of sub-blocks in parallel.

15. The method of claim 14, wherein selecting the set of sub-blocks of the first block further comprises:
determining whether a media healthy metric associated with a sub-block of a plurality of sub-blocks of the first block satisfies a threshold criterion; and
responsive to determining that the media healthy metric associated with the sub-block satisfies the threshold criterion, selecting the sub-block.

16. The method of claim 10, wherein performing the in-field read operation to the first block further comprises:
determining a sub-block of the first block; and
performing the in-field read operation to the sub-block of the first block.

17. The method of claim 10, wherein the in-field read operation comprises applying to the wordline a pass voltage followed by a bias voltage, wherein the floating voltage phase occurs during applying the bias voltage.

18. A non-transitory computer-readable storage medium comprising instructions that, when executed by a processing device, cause the processing device to perform operations comprising:
performing a program operation to program data to a first block of a plurality of blocks of the memory device, wherein the program operation does not include a program verify phase;
performing an in-field read operation to the first block, wherein the in-field read operation includes a voltage floating phase, and wherein a voltage supply to a wordline is withdrawn during the voltage floating phase; and
responsive to detecting a read status failure as a result of performing the in-field read operation, marking and retiring the first block and performing the program operation to program the data to a second block of the plurality of blocks of the memory device.

19. The non-transitory computer-readable storage medium of claim 18, wherein performing the in-field read operation to the first block further comprises:
selecting a set of sub-blocks of the first block; and
performing the in-field read operation on each sub-block of the set of sub-blocks in parallel.

20. The non-transitory computer-readable storage medium of claim 19, wherein selecting the set of sub-blocks of the first block further comprises:
determining whether a media healthy metric associated with a sub-block of a plurality of sub-blocks of the first block satisfies a threshold criterion; and
responsive to determining that the media healthy metric associated with the sub-block satisfies the threshold criterion, selecting the sub-block.
